(19) United States
(12) Patent Application Publication
(10) Pub. No.: US 2026/0215287 A1
(43) Pub. Date: Jul. 23, 2026

(54) ADVANCED LAND SIDE CAPACITOR (ALSC)

(71) Applicant: Advanced Micro Devices, Inc., Santa Clara, CA (US)

(72) Inventor: Mahadevan SURYAKUMAR, Austin, TX (US)

(21) Appl. No.: 18/990,697

(22) Filed: Dec. 20, 2024

(51) Int. Cl. H01L 23/00; H01L 23/498; H01L 23/64

(52) U.S. Cl. CPC H10W 44/601; H10W 90/701; H10W 90/724

(57) ABSTRACT

An integrated circuit (IC) device package includes a PCB circuitry having a back side opposing a topside, a package substrate having a die side and a landside that is electrically connected to the topside of the PCB circuitry, a die electrically connected to the die side of the package substrate; and a landside capacitor, the landside capacitor electrically connected to both the landside of the package substrate and the topside of the PCB circuitry

### TECHNICAL FIELD

Examples herein relate to integrated circuit (IC) devices. In particular, examples herein relate to an IC device package including a land side capacitor.

### BACKGROUND

In recent years, integrated circuit (IC) devices, have become increasingly faster, more powerful, and smaller in size. As IC devices have become smaller with increasing frequencies, noise and impedance experienced throughout the circuitry increase due to inductive and capacitive parasitics.

To reduce noise and impedance, bypass capacitors are mounted to IC device packages. Bypass capacitors include die side capacitors that are placed on the die side of a package substrate, back side capacitors that are mounted on a back side of a circuitry board mounted to the package substrate, and topside capacitors mounted to a topside of the circuitry board.

“Hot spots” on the die are localize high switching activity areas (i.e., areas on the die that are hotter and have higher rates of current switching activity than surrounding regions with respect to time). These nodes need a high quality power delivery connection from the capacitor and the power supply, but this is impeded by the parasitics of the planes and vias in the package substrate. The parasitics limit the effectiveness of die side capacitors. To combat this, landside capacitors are mated to the landside of the package substrate as the power delivery to the die can be more robust. However, landside capacitors form factors are limited by the IC device package size and the solder ball height. In one or more examples, to mount a landside capacitor to the package substrate, solder balls that electrically connects the package substrate to the PCB circuitry need to be removed to allow room to mount the landside capacitor(s) to the package substrate. Problematically, solder balls transmit signals and current between the PCB circuitry and the package substrate, and removing the solder balls reduces the number of ground and power balls and also the current transferred between the PCB circuitry and the package substrate is impacted.

### SUMMARY

According to one or more examples, an integrated circuit (IC) device package includes a printed circuit board (PCB) circuitry having a back side opposing a topside, a package substrate having a die side and a landside that is electrically connected to the topside of the PCB circuitry, a die electrically connected to the die side of the package substrate; and a landside capacitor, the landside capacitor electrically connected to both the landside of the package substrate and the topside of the PCB circuitry.

According to one or more examples, an IC device package includes a PCB circuitry having a back side opposing a topside, the PCB circuitry having a recess formed within a portion of the topside, a package substrate having a landside that is electrically connected to the topside of the PCB circuitry and a die side, a die electrically connected to the die side of the package substrate, and a landside capacitor, the landside capacitor electrically connected to both the package substrate and the PCB circuitry using a frame disposed within the recess.

According to one or more examples, A method includes electrically connecting a package substrate to a printed circuit board (PCB) circuitry, wherein electrically connecting the package substrate to the PCB circuitry comprises electrically connecting a landside capacitor to both a landside of the package substrate and a topside of the PCB circuitry, the topside of the PCB circuitry facing the landside of the package substrate, electrically connecting a die side capacitor to a die side of the package substrate, the die side opposing the landside of the package substrate, and electrically connecting a die to the die side of the package substrate

### BRIEF DESCRIPTION OF DRAWINGS

FIG. 1 illustrates an integrated circuit (IC) device package having a landside capacitor mounted to both a package substrate and a board PCB circuitry, according to one or more examples.

FIG. 2 illustrates an IC device package including a recess formed on a portion of a PCB circuitry, according to one or more examples.

FIG. 3A illustrates an example frame used to electrically connect a landside capacitor to both a PCB circuitry and a package substrate of an IC device package that includes a recess formed on a portion of a PCB circuitry, according to one or more examples.

FIG. 3B illustrates the example frame used to electrically connect a landside capacitor to both a PCB circuitry and a package substrate of an IC device package that does not include a recess formed on a portion of a PCB circuitry, according to one or more examples.

FIG. 4 illustrates a method 400 for forming an IC device package having a landside capacitor mounted to both a package substrate and a board PCB circuitry, according to one or more examples

FIG. 5 illustrates a computing system including an IC device package having a landside capacitor connected to both a package substrate and a PCB circuitry, according to one or more examples

### DETAILED DESCRIPTION

An example IC device package includes a die electrically connected to a package substrate that is further electrically connected to a PCB circuitry. The die is electrically connected to the package substrate and the package substrate is electrically connected to the PCB circuitry using solder balls. The solder balls allow for electrical signals (e.g., current and voltage signals) to be transmitted between the die, the package substrate, and the PCB circuitry. However, as IC device packages are becoming smaller and increased signal frequencies are being used, noise and impedances experienced throughout the IC device package increases due to inductive and capacitive parasitics.

To combat the increase in noise and impedances, bypass capacitors are used. Bypass capacitors are typically placed near “hot spots” to increase the efficiency of the bypass capacitors. Bypass capacitors include die side capacitors that are placed on the die side of a package substrate, back side capacitors that are mounted on a back side of a circuitry board mounted to the package substrate, and topside capacitors mounted to a topside of the circuitry board. In one or more examples, “hot spots” on the package substrate (i.e., areas on the package substrate that are hotter (higher temperatures) than surrounding regions) cause increases in inductance that limit the effectiveness of die side capacitors. To combat the increases in inductance, landside capacitors are mated to the landside of the package substrate. However, form factors of landside capacitors are limited by the IC device package size and the location, size, and quantity of solder balls. Typically, to mount a landside capacitor the package substrate, solder balls need to be removed to allow room to mount the landside capacitor(s) to the package substrate. Problematically, removing the solder balls (i.e., the metal connection between the PCB circuitry and the package substrate) weakens the signal strength and reduces the current transferred between the PCB circuitry and the package substrate.

Examples herein relate to electrically coupling a landside capacitor to a package substrate and a PCB circuitry without reducing the metal connection (such as the quantity of solder balls) between a PCB circuitry and a package substrate of an IC device package. Advantageously, by not reducing the metal connection between the PCB circuitry and the package substrate of an IC device package, the electrical signal path between a PCB circuitry and a package substrate of an IC device package remains unaffected,

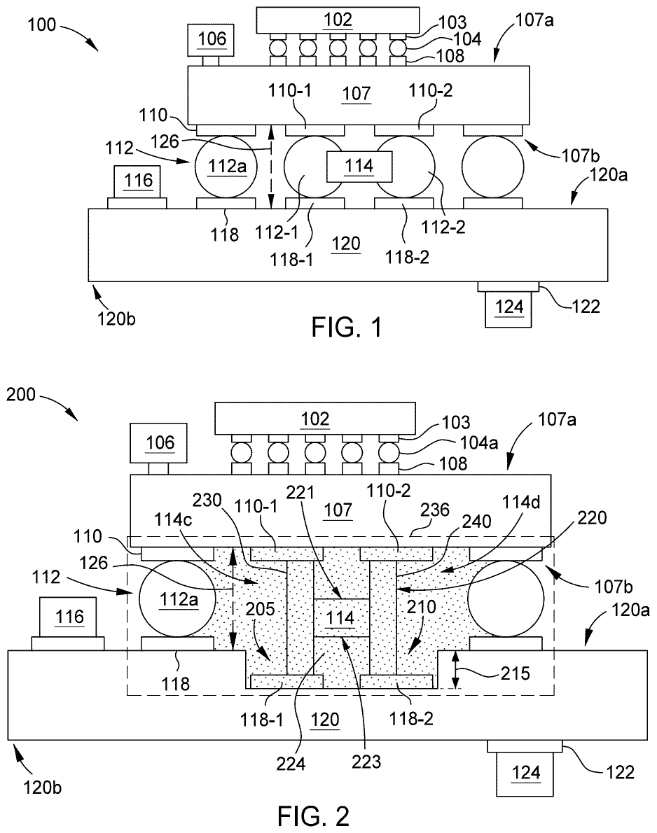

FIG. 1 illustrates an integrated circuit (IC) device package having a landside capacitor mounted to both a package substrate and a PCB circuitry, according to one or more examples. In one or more examples, an IC device package 100 package includes a PCB circuitry 120 electrically connected to a package substrate 107 which is further electrically connected to a die 102. In one or more examples, the PCB circuitry 120 used as motherboard or system board for a personal computer (PC), ultrabook, tablet, mobile device, or any other suitable device. In another example, the PCB circuitry 120 is a daughter card that is to be placed on a motherboard. In one more examples, the PCB circuitry 120 is a conventional multilayer PCB circuitry that includes PCB build-up layers. As understood by those with ordinary skill in the art, the PCB build-up layers include a dielectric material and PCB circuitry components disposed therein such as metal lines, vias, or the like that are used to transmit electric signal(s) throughout the PCB circuitry 120 and to the package substrate 107. For example, the PCB circuitry 120 is connected to a source (such as a power source) and uses the PCB circuitry components disposed within the PCB build-up layers to connect the power and ground of the platform power source to the power and ground bumps on the die 102 through the PCB circuitry 120.

The PCB circuitry 120 includes a topside 120a located on a top surface of PCB circuitry 120 that opposes a back side 120b located on a bottom surface of the PCB circuitry 120. The PCB circuitry 120 further includes one or more topside pads 118 disposed on the topside 120a. The PCB circuitry 120 also includes a back side pad 122 disposed on the back side 120b. In one or more examples, the topside pads 118 and the back side pad 122 include a metal material such as copper or another type of metal, or another type of conductive material. In one or more examples, the topside pads 118 are used to electrically connect the topside 120a of the PCB circuitry 120 to the package substrate 107 and any other suitable electrical component (if any). The back side pad 122 is used to electrically connect the back side 120b of the PCB circuitry 120 to any suitable electrical component (if any). Although FIG. 1 illustrates 5 topside pads 118 and 1 back side pad 122, any suitable quantity of topside pads and back side pads may be disposed on the PCB circuitry 120.

In one or more examples, the package substrate 107 includes a landside 107b formed on a bottom surface of the package substrate 107 and a die side 107a formed on a top surface of the package substrate 107 that opposes the landside 107b. The landside 107b faces the PCB circuitry 120 and the die side 107a faces the die 102. The package substrate 107 includes landside pads 110 located on the landside 107b of the package substrate 107 and die side pads 108 located on the die side 107a of the package substrate 107. In one or more examples, the landside pads 110 and the die side pads 108 include a metal material such as copper, another type of metal, or another type of conductive material. Although FIG. 1 illustrates 4 landside pads 110 and 5 die side pads 108, any suitable quantity of landside pads and die side pads may be disposed on the package substrate 107. Furthermore, although FIG. 1 illustrates 4 topside pads 118 and 1 back side pad 122, any suitable quantity of topside pads and back side pads may be disposed on the PCB circuitry 120.

The package substrate 107 is electrically connected to the PCB circuitry 120 via a ball gate array (BGA) 112 that includes one or more solder balls 112a. In one or more examples, the solder balls 112a are electrically connected to corresponding (i.e. aligned) topside pads 118 and landside pads 110. Although the BGA 112 illustrates 4 solder balls 112a used to electrically connect the package substrate 107 and the PCB circuitry 120, this is for example purposes only. In one or more examples, the PCB circuitry 120 and the package substrate are separated by a distance 126. The distance 126 may be from about 300 to about 800 μm. Stated differently the solder balls 112a are disposed between in the area between the package substrate 107 and the PCB circuitry 120.

Any suitable quantity of solder balls 112a may be used to connect the PCB circuitry 120 and the package substrate 107. As understood by those with ordinary skill in the art, the solder balls 112a between the package substrate 107 and the PCB circuitry 120 are used to transmit electrical signal(s) from the PCB circuitry 120 to the package substrate 107.

In one or more examples, the package substrate 107 is a conventional multilayer substrate. Stated differently, the package substrate 107 includes one or more package substrate build-up layers disposed therein. As understood by those with ordinary skill in the art, the package substrate build-up layers include a dielectric material and package substrate circuitry components disposed therein such as metal lines, vias, or the like that are used to transmit electric signal(s) and current received via the solder balls 112a throughout the package substrate 107 (and to the die 102).

As noted above, the package substrate 107 is electrically connected to the die 102. In one or more examples, the package substrate 107 is electrically connected to the die using a BGA 104 that includes one or more solder balls 104a that are electrically connected to corresponding (aligned) die side pads 108 die pads 103 (or bumps) formed on a bottom surface 102a of the die 102. In the same manner described above, any suitable quantity of die pads 103 on the bottom surface 102a of the die 102. Furthermore, any suitable quantity of solder balls 104a may be used to electrically connect the die 102 and the package substrate 107.

As noted above, to reduce the noise and impedance experienced by the IC device package 100, bypass capacitors are used. For example, as shown in FIG. 1, a back side capacitor 124 is electrically connected to the back side 120b via the back side pad 122. A topside capacitor 116 is electrically connected to the topside 120a via one of the topside pads 118. A die side capacitor 106 is electrically connected to the die side 107a via one of the die side pads 108. Although 1 back side capacitor 124, 1 topside capacitor 116, and 1 die side capacitor 106 are illustrated in FIG. 1, any suitable quantity of back side capacitors, topside capacitors, and die side capacitors may be electrically connected to the IC device package 100. Typically bypass capacitors are placed near “hot spots” on the package substrate 107 (i.e.,, areas on the die 102 that are hotter and have higher rates of current switching activity than surrounding regions with respect to time). However, die side capacitors 106 have compromised power delivery connections due to the die side capacitors 106 being much further away from the source and a high level parasitics (resistance and inductance) reduce the effectiveness of the die side capacitors 106.

To increase the efficiency of the die side capacitor 106, a landside capacitor 114 is attached to the landside 107b of the package substrate 107. However, the landside capacitor 114 is limited by the IC device package size and the size, location, and quantity of solder balls 112a. For example, the typical landside capacitor is mounted to one or more of the landside pads 110 (i.e., only the package substrate 107) using a dense mesh of vertical vias. Therefore, the landside capacitor requires removal of one or more of the solder balls 112a that electrically connect the package substrate 107 and the PCB circuitry 120. Stated differently, one or more solder balls 112a are removed to unoccupy landside pads 110 that are used to electrically connect the landside capacitor 114 to the package substrate 107. As understood by those with ordinary skill in the art, the removal of the solder balls 112a weakens the electrical connection (e.g. lessens the power delivery connect robustness) between the PCB circuitry 120 and the package substrate 107. Therefore, examples herein relate to a landside capacitor electrically connected to both the landside 107b of the package substrate 107 and the topside 120a of the PCB circuitry 120 that does not compromise the electrical connection between the package substrate 107 and the PCB circuitry 120.

Referring back to FIG. 1, a landside capacitor 114 is electrically connected to one or more of the solder balls 112a. Stated differently, the landside capacitor 114 is electrically connected to (i.e., mated to) an adjacent pair of solder balls 112a. For example, the landside capacitor is electrically connected to landside pads 110-1 and 110-2 and topside pads 118-1 and 118-2 through the solder balls 112-1 and 112-2. Advantageously, the landside capacitor 114 acts as solder ball(s) and a capacitor concurrently. Therefore, the landside capacitor 114 can be electrically connected to the package substrate 107 and the PCB circuitry 120 without a reduction of the electrical signal path between the package substrate 107 and the PCB circuitry 120. Thus, the inductance of the package substrate 107 is reduced without limiting the electrical connection between the package substrate 107 and the PCB circuitry 120.

As the size of electronic devices are shrinking, the size of IC device packages are increasingly getting smaller, including, but not limited to, the vertical direction. Stated differently, due to the smaller sizes of electronic devices, the distance 126 is becoming increasingly smaller. As noted above, the form factor of the landside capacitor 114 is limited based on the size of the IC device package 100. Therefore, if the distance 126 is limited due to size requirements, the size of the landside capacitor 114 needs to be reduced. However, as understood by those with ordinary skill in the art, reducing the size of the land size capacitor (i.e., the quantity of plates) reduces the maximum charge that can be stored by (e.g., capacitance of) the landside capacitor.

To combat this, a recess is formed in a portion of the PCB circuitry 120 to increase the distance between the PCB circuitry 120 and the package substrate 107 along the portion to fit a suitable landside capacitor. Problematically, as noted above, forming the recess and electrically coupling the landside capacitor requires removal of one or more solder balls 112a.

As understood by those with ordinary skill in the art, the PCB circuitry 120, the package substrate 107, and the die 102 the may also have additional suitable components and/or suitable packages mounted thereon

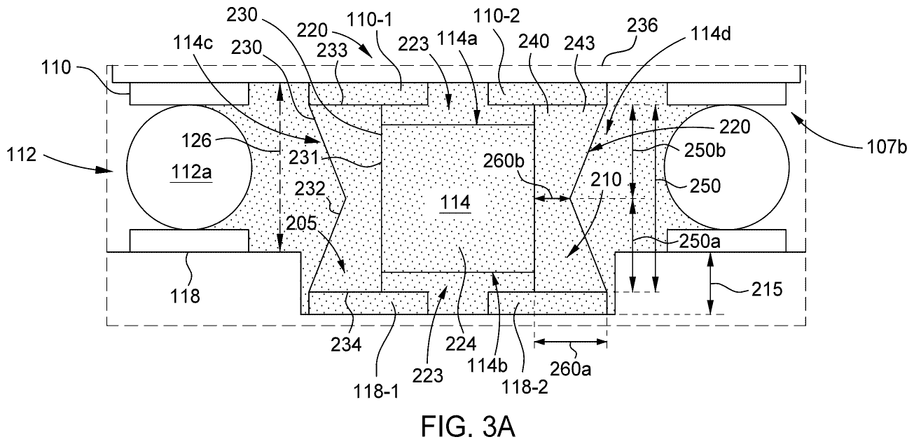

FIG. 2 illustrates an IC device package including a recess formed on a portion of a PCB circuitry, according to one or more examples. In one or more examples, as described above, an IC device package 200 includes a recess 205 that is formed within a portion 210 of the PCB circuitry 120 located between the landside 107b and the topside 120a. As illustrated in FIG. 2, the recess 205 increases the distance 126 between the package substrate 107 and the PCB circuitry 120, within the portion 210, allowing for a land size capacitor of a suitable size to be disposed between the package substrate 107 and the PCB circuitry 120. Furthermore, topside pads 118 are formed in the recess 205 for electrically connecting the landside capacitor 114 to the PCB circuitry 120. The recess 205 has a depth 215 (i.e., increases the distance 126 by a distance) between 80 and 120 μm.

In one or more examples, the landside capacitor 114 is connected to the package substrate 107 and the PCB circuitry 120 via a frame 220. The frame 220 may comprise the same material as the solder balls 112a or a different conductive material. Advantageously, the frame 220 is shaped to include a first structure 230 and a second structure 240 (described in more detail below) such that the frame 220 is able to experience the stress and strain that the IC device package 200 undergoes while still securing the landside capacitor 114 and while still contributing to the electronic coupling of the PCB circuitry 120 and the package substrate 107. Stated differently, the frame 220 performs the same function of solder balls 112a while ensuring the landside capacitor 114 remains secured. In one or more examples, the recess 205 is optional and the frame 220 is coupled to the topside 120a of the PCB circuitry 120 and the land side 107a of the package substrate. Details of the frame are discussed in more detail below.

In one or more examples, a bottom gap 223 is formed between the portion of the topside 120a within the portion 210 and a bottom surface 114b of the landside capacitor 114, and a top gap 221 is formed between the landside 107b and a top surface 114a of the landside capacitor 114. A first side gap 114c is formed between the first structure 230 and a solder ball 112a that is adjacent to the first structure 230. A second side gap 114d is formed between the second structure 240 and a solder ball 112a that is adjacent to the second structure 240. In one or more examples, as illustrated in FIG. 2, the frame 220 may be further secured via an optional under fill material 224 that surrounds the frame 220. Stated differently, the under fill material 224 fills the top gap 221, the bottom gap 223, the first side gap 114c and the second side gap 114d. In one or more examples, the under fill material 224 is an epoxy material. The under fill material 224 advantageously further secures the frame 220 and makes the frame 220 more reliable by improving the ability of the frame to withstand additional stresses while still maintaining electrical robustness. In examples in which the recess 205 is not included, the bottom gap 223 is formed between the bottom surface 114b of the landside capacitor 114 and the topside 120a. Additionally, in one or more examples, the underfill material 224 can also encapsulate one or more solder balls 112a.

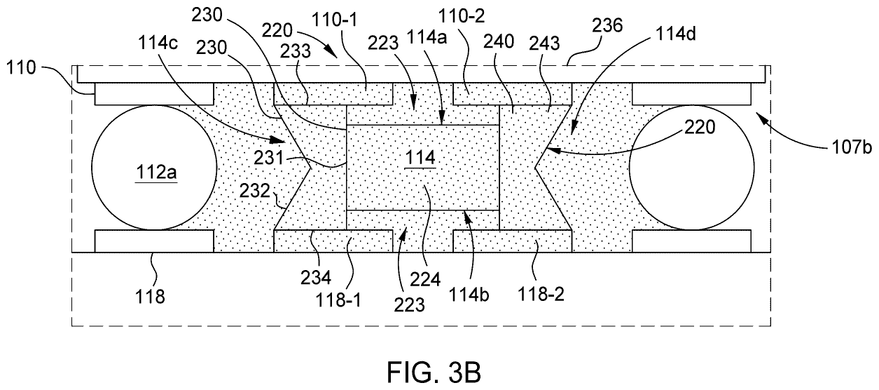

FIG. 3A illustrates the frame used to electrically connect a landside capacitor to both a PCB circuitry and a package substrate of an IC device package that includes a recess formed on a portion of a PCB circuitry, according to one or more examples. FIG. 3A is a zoomed in view of box 236 shown in FIG. 2.

As illustrated in FIG. 3A, the frame 220 includes a first structure 230 and a second structure 235 that face each other. The first structure 230 includes a first side 231 that opposes and a second side 232 and a first top surface 233 that opposes a first bottom surface 234. The second structure 240 includes a third side 241 that opposes and a fourth side 242 and a second top surface 243 that opposes a second bottom surface 244. In one or more examples, the first top surface 233 is coupled to a landside pad 110-1 and the first bottom surface 234 is coupled to a topside pad 118-1. The second top surface 243 is coupled to a landside pad 110-2 and the second bottom surface 244 is coupled to a topside pad 118-2.

The first side 231 and the third side 241 face one another. The first top surface 233, and the second top surface 243 are both electrically connected to respective landside pads 110 positioned within the recess 205. The first bottom surface 234 and the second bottom surface 244 are both electrically connected with receptive topside pads 118 positioned within the recess 205 (if included). Advantageously, as noted above, the frame 220 connects the landside capacitor 114 to the PCB circuitry 120 and the package substrate 107 while still contributing to the electrical coupling of the PCB circuitry 120 and the package substrate 107.

In one or more examples, the first structure 230 and the second structure are angled structures. However, the shape of the first structure 230 and the second structure described herein is for example purposes only. The first structure 230 and the second structure 240 may be rectangular shaped, square shaped, circular shaped, or be any other suitable shape so long as the frame 220 is a reliable metallurgical joint that can survive the required thermal and mechanical stresses while maintaining electrical robustness.

In one or more examples, the first structure 230 and the second structure 240 have a height 250 and a width. In one or more examples, the width changes between a first width 260a and a second width 260b throughout the height 250. In one or more examples, the width of the first structure 230 and the second structure 240 decreases from the first width 260a to the second width 260b from a respective first bottom surface 234 or second bottom surface 244 to a first height 250a. The width of the first structure 230 and the second structure 240 decrease from the second width 260b back to the first width 260a from the first height 250a to a second height 250b (or to a respective first top surface 233 or second top surface 243).

In one or more examples, as also described above the optional under fill material 224 can surround the frame 220 in the same manner described above.

FIG. 3B illustrates the frame used to electrically connect a landside capacitor to both a PCB circuitry and a package substrate of an IC device package that does not include a recess formed on a portion of a PCB circuitry, according to one or more examples. As illustrated in FIG. 3B, the frame 220 may be formed between the landside 107b and the topside 120a. Also as noted above, the optional epoxy material may surround the frame 220 in the same manner described above.

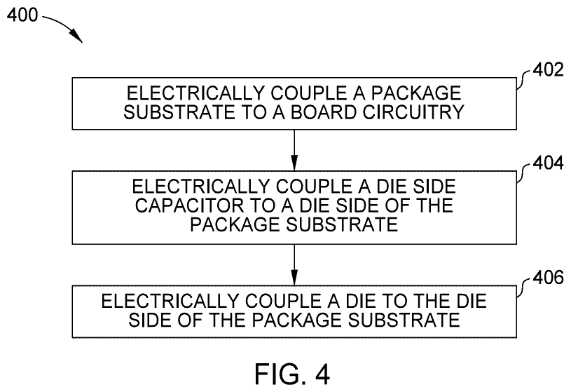

FIG. 4 illustrates a method 400 for forming an IC device package having a landside capacitor mounted to both a package substrate and a board PCB circuitry, according to one or more examples. FIG. 4 is described with reference to FIGS. 1-3

At operation 402 of the method 400, the package substrate 107 is connected to the PCB circuitry 120. The PCB circuitry 120 is electrically connected to the package substrate 107 via the BGA 112 in the manner described in FIGS. 1-3 above. In one or more examples, coupling the package substrate 107 to the PCB circuitry 120 includes coupling a landside capacitor 114 to both the topside 120a of the PCB circuitry 120 and the landside 107b of the package substrate 107. In one or more examples, as illustrated in FIG. 1 the landside capacitor may be electrically connected to adjacent solder balls 112a. In other examples, as illustrated in FIGS. 2-3, if the PCB circuitry 120 includes the recess 205, the landside capacitor is connected to both the topside 120a of the PCB circuitry 120 and the landside 107b of the package substrate 107 via the frame 220.

At operation 404 of the method 400, a die side capacitor 106 is electrically connected to the die side 107a of the package substrate 107. As shown in FIGS. 1-2 above the die side capacitor 106 is electrically connected to the die side 107a of the package substrate 107 via a die side pad 108.

At operation 406 of the method 400, a die 102 is electrically connected to the die side 107a of the package substrate 107. As shown in FIGS. 1-2 above the die 102 is electrically connected to the die side 107a of the package substrate 107 via the BGA 104.

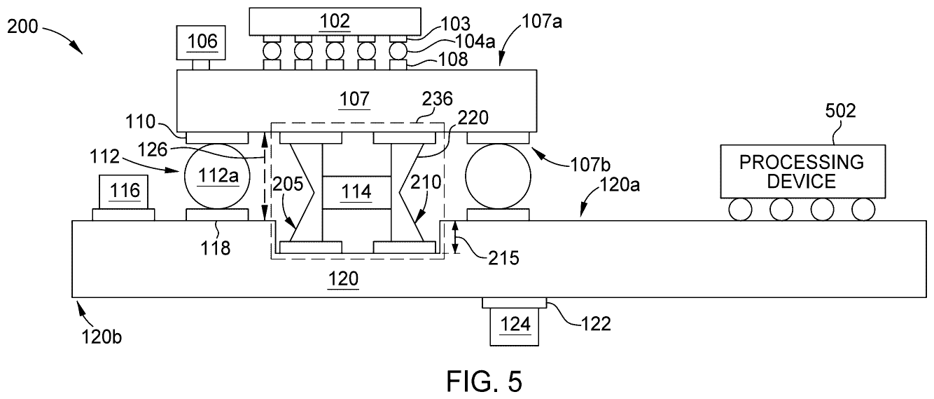

FIG. 5 illustrates a computing system 500 including an IC device package 200 having a landside capacitor 114 connected to both a package substrate 107 and a PCB circuitry 120, according to one or more examples. Although the computing system is shown as including IC device package 200, it is understood that the computing system 500 can include the IC device package 100 in addition to or alternately to the IC device package 200. In one or more examples, the computing system 500 further includes a processing device 502 connected to the topside 120a of the PCB circuitry 120. The processing device 502 can be any suitable processing device, including, but not limited to, a central processing unit (CPU), graphics processing unit (GPU), or the like. Although the processing device 502 is illustrated as a single processing device, the computing system may include a stack of any quantity of processing devices connected to the topside 120a of the PCB circuitry 120. Each processing device of the stacked of the processing devices may be a same or different type of processing device.

The computing system 500 is not limited to one package substrate 107 connected to the PCB circuitry 120 and one die 102 connected to the package substrate 107. Any suitable quantity of package substrates 107 and die 102 may be included in the computing system 500 having the capacitor layout described in FIG. 2 (or FIG. 1)

Furthermore multiple systems 500 may be connected to each other in a network.

Advantageously, as noted above examples herein relate to connecting a landside capacitor 114 to a landside 107b of a package substrate 107 and a topside 120a of a package substrate 107 without impeding the electrical path between the package substrate 107 and the PCB circuitry 120.

While the foregoing is directed to specific examples, other and further examples may be devised without departing from the basic scope thereof, and the scope thereof is determined by the claims that follow.

What is claimed is:

1. An integrated circuit (IC) device package comprising:
a printed circuit board (PCB) circuitry having a back side opposing a topside;
a package substrate having a die side and a landside that is electrically connected to the topside of the PCB circuitry;
a die electrically connected to the die side of the package substrate; and
a landside capacitor, the landside capacitor electrically connected to both the landside of the package substrate and the topside of the PCB circuitry.

2. The IC device package of claim 1, further comprising a back side capacitor electrically connected to the back side of the PCB circuitry.

3. The IC device package of claim 1, wherein the topside of the PCB circuitry is electrically connected to the landside of the package substrate via a ball gate array including a plurality of solder balls, and wherein the landside capacitor is mated with an adjacent pair of solder balls.

4. The IC device package of claim 1, further including a recess formed within a portion of the PCB circuitry.

5. The IC device package of claim 4, wherein the landside capacitor is electrically connected to the topside of the PCB circuitry and the landside of the package substrate via a frame.

6. The IC device package of claim 5, wherein the frame includes a first structure having a first top surface that opposes a first bottom surface and a second structure having a second top surface that opposes a second bottom surface.

7. The IC device package of claim 6, wherein the first structure and the second structure have a width that changes along a height of the first structure and the second structure.

8. The IC device package of claim 5, further comprising an under fill material surrounding the frame.

9. The IC device package of claim 1, further comprising a topside capacitor electrically connected to the topside of the PCB circuitry.

10. An integrated circuit (IC) device package comprising:
a printed circuit board (PCB) circuitry having a back side opposing a topside, the PCB circuitry having a recess formed within a portion of the topside;
a package substrate having a landside that is electrically connected to the topside of the PCB circuitry and a die side;
a die electrically connected to the die side of the package substrate; and
a landside capacitor, the landside capacitor electrically connected to both the package substrate and the PCB circuitry using a frame disposed within the recess.

11. The IC device package of claim 10, wherein the frame includes a first structure having a first top surface that opposes a first bottom surface and a second structure having a second top surface that opposes a second bottom surface.

12. The IC device package of claim 11, wherein the first structure and the second structure have a width that changes along a height of the first and second structures.

13. The IC device package of claim 12, wherein the width of the first structure and the second structure changes from a first width to a second width throughout a first height of the height and changes from the second width to the first width between the first height and a second height of the height, the first width being different from the second width.

14. The IC device package of claim 10, further comprising die side capacitor electrically connected to the die side of the package substrate.

15. The IC device package of claim 10, further comprising a topside capacitor electrically connected to the topside of the PCB circuitry, and a back side capacitor electrically connected to the back side of the PCB circuitry.

16. The IC device package of claim 10, further comprising an under fill material surrounding the frame.

17. A method comprising:
electrically connecting a package substrate to a printed circuit board (PCB) circuitry, wherein electrically connecting the package substrate to the PCB circuitry comprises electrically connecting a landside capacitor to both a landside of the package substrate and a topside of the PCB circuitry, the topside of the PCB circuitry facing the landside of the package substrate;
electrically connecting a die side capacitor to a die side of the package substrate, the die side opposing the landside of the package substrate; and
electrically connecting a die to the die side of the package substrate.

18. The method of claim 17, wherein electrically connecting the landside capacitor to both a landside of the package substrate and the topside of the PCB circuitry comprises mating the landside capacitor to a ball gate array including a plurality of solder balls that are electrically connected to both the landside of the package substrate and the topside of the PCB circuitry, and wherein the landside capacitor is mated with an adjacent pair of solder balls.

19. The method of claim 17, wherein electrically connecting the landside capacitor to both the landside of the package substrate and the topside of the PCB circuitry comprises mating the landside capacitor using a frame that is electrically connected to both the landside of the package substrate and the topside of the PCB circuitry.

20. The method of claim 19, wherein the frame has a height and includes a first structure having a first top surface that opposes a first bottom surface and a second structure having a second top surface that opposes a second bottom surface, and a width of the first structure and the second structure changes from a first width to a second width throughout a first height of the height and changes from the second width to the first width between the first height and a second height, the first width being different from the second width.
